(19) United States
(12) Patent Application Publication
(10) Pub. No.: US 2007/0051622 A1
(43) Pub. Date: Mar. 8, 2007

(54) Simultaneous ion milling and sputter deposition

(75) Inventors: Xianmin Tang, San Jose, CA (US); Anantha Subramani, San Jose, CA (US); Praburam Gopalraja, San Jose, CA (US); Jianming Fu, Palo Alto, CA (US); Jick Yu, San Jose, CA (US)

Correspondence Address: LAW OFFICES OF CHARLES GUENZER;ATTN: APPLIED MATERIALS, INC., 2211 PARK BOULEVARD, P.O. BOX 60729, PALO ALTO, CA, 94306, US

(73) Assignee: Applied Materials, Inc.

(21) Appl. No.: 11/218,403

(22) Filed: Sep. 2, 2005

(51) Int. Cl. C23C 14/00

(52) U.S. Cl. 204/298.01

(57) ABSTRACT

A magnetron sputter reactor including an ion beam source producing a linear beam that strikes the wafer center at an angle of less than 35°. The linear beam extends across the wafer perpendicular to the beam but has a much short dimension along the beam propagation axis while the wafer is being rotated. The ion source may be an anode layer source having a plasma loop between an inner magnetic pole and a surrounding outer magnetic pole with anode overlying the loop with a closed-loop aperture. The beams from the opposed sides of the loop are steered together by making the outer pole stronger than the inner pole. The aperture width may be varied to control the emission intensity.

### FIELD OF THE INVENTION

The invention relates generally to sputtering of materials. In particular, the invention relates to the combination of sputtering and etching or milling performed in the same chamber.

### BACKGROUND ART

Sputtering, alternatively called physical vapor deposition (PVD) in its most common implementation, is widely used to deposit layers of metals and related materials in the fabrication of semiconductor integrated circuits. Typically, a target of the material to be sputtered is placed in opposition to a generally circular wafer to be sputter coated with a material at least partially originating from the target. Electrical means discharge an argon working gas into a plasma, and the resulting positively charged argon ions are attracted to the negatively biased target with enough energy to dislodge (sputter) atom-sized metal particles from the target. Some of these particles travel to the wafer and are deposited in a layer on the wafer surface. In reactive sputtering, a reactive gas, for example, nitrogen, is simultaneously admitted into the sputter reactor. The nitrogen chemically reacts with the sputtered metal atoms to form a metal nitride layer, for example, of tantalum nitride, on the wafer.

Advanced integrated circuits typically include several metallization layers electrically connected by thin vertical vias extending through dielectric layers separating the respective metallization layers. While the lateral dimensions of the vias has decreased to 0.13 μm in advanced commercial devices and will be reduced further in the future, the thickness of the dielectric is constrained by considerations of dielectric discharge and cross talk to be no less than about 0.7 μm, and it may be up to 1.5 μm in some more complex interconnect structures. As a result, the aspect ratio of the via holes into which the metal is to be coated may be 5 and above. The situation is a little more complex in dual-damascene structures, but the trend in the technology is to coat metal into holes of increasingly higher aspect ratio. Sputtering is fundamentally a ballistic process which is ill suited to penetrating deeply into such holes.

Many advanced integrated circuits use copper metallization because of copper's low resistivity and electromigration compared to aluminum. Copper may be alloyed up to 10 wt % with dopants or impurities. A typical copper via structure is illustrated in the cross-sectional view of FIG. 1. A conductive feature 10 is formed in or over a lower-level dielectric layer 12 composed of silicon dioxide, a silicate glass, or a low-k dielectric material. The conductive feature 10 may be a lower-level metallization of copper. The situation is somewhat more complicated if the conductive feature is a semiconducting silicon portion formed in a silicon substrate, but the metallization problems are much the same. An upper-level dielectric 14 is deposited over the lower-level dielectric layer 12 and its conductive feature 10. Patterned oxide etching forms a via hole 16 extending through the upper dielectric layer 14 in the area of the conductive feature. The via hole 16 preferably has a nearly vertical profile and, as mentioned before, its aspect ratio may be 5 or greater. Such etching is available using a plasma formed from a fluorocarbon, such as C₄F₆ and argon, with negative wafer biasing, a process called reactive ion etching.

A barrier is needed on the sides of the via hole 16 to prevent the copper filled into the via hole 16 from diffusing into the oxide dielectric 14 and causing it to short. Also, copper does not stick well to oxide. A thin barrier layer 18 of tantalum nitride (TaN), typically in combination with a Ta layer, serves both purposes. Both layers can be sputter deposited from a tantalum target. Special sputtering techniques are usually employed to allow nearly conformal sputtering onto the sides and bottom of the via hole 16. One such technique called self-ionized plasma (SIP) sputtering, as described by Fu et al. in U.S. Pat. No. 6,290,825, uses a small but strong unbalanced nested magnetron and high target power to produce a relatively high fraction of the sputtered metal atoms that are ionized. The size of the magnetron can be further decreased, and hence the ionization fraction further increased, without degrading sputter uniformity using a planetary scanning mechanism, such as disclosed by Miller et al. in U.S. Pat. No. 6,852,202. The wafer is biased negatively DC, typically from a capacitively coupled RF source, to thereby create a negative self-bias on the wafer adjacent the sputtering plasma. The negative bias draws the positively charged metal ions deep within the via hole. Furthermore, the unbalanced magnetron produces magnetic components which project from the target toward the wafer, thus expanding the plasma and guiding the metal ions toward the wafer. The preferred technique for coating tantalum layers combines the SIP diode sputtering with an RF coil wrapped around the chamber interior to increase the plasma density. However, for sputtering of thin copper layers into vias the straightforward SIP sputtering is often preferred. Either technique is capable of producing relatively thick sidewall 20 and bottom 22 within the hole 16 compared to a thicker field 24 on the planar top of the dielectric layer 24. However, the sidewall 20 tends to vary somewhat in thickness having a thin portion 26 near the center of the sidewall. To assure that the barrier layer 18 covers the entire sidewall 20 to a minimum thickness of a few nanometers, the average sidewall thickness is somewhat more. That is, the barrier sidewalls 20, particularly their top portions, tend to significantly narrow the hole 16 being filled, thus increasing its aspect ratio.

Additionally, the sputtering geometry favors the formation of overhangs 28 at the exposed top corners of the hole 16. Such overhangs 28 significantly increase the effective aspect ratio of the hole during the final stages of the barrier deposition, thus making the uniform sidewall and bottom coverage even more difficult. Furthermore, even if chemical electroplating (ECP) is used to fill the hole with copper, a thin copper seed and electrode layer 30 needs to be coated onto the barrier layer 18, as illustrated in the cross-sectional view of FIG. 1. Sputtering is the favored technique for depositing the seed layer because of its lower cost and generally more favorable surface characteristics relative to copper deposited by chemical vapor deposition (CVD). However, sputtering copper into the via hole 16 partially closed by the barrier overhangs 28 is difficult because of the high effective aspect ratio. Further, sputtered copper tends to form its own overhangs 32 forming a constricted throat 34 so that the final stage of the copper seed deposition is even more difficult and it is possible that the copper overhangs 32 bridge the hole 16 and completely close the throat 34, forming a void within the via hole 16. Even if the via hole 16 remains unbridged at the beginning of the electrochemical plating (ECP) copper fill, the constricted throat 34 presents significant problems to completing the ECP fill. ECP produces a generally conformal coating so that the narrow throat 34 is being filled proportionately faster than the lower, wider portion of the hole 16 and may thus close and create an included void. The effect is exacerbated by the need to replenish the ECP electrolyte within the hole 16 through the rapidly closely throat 34.

The SIP target is generally planar. Shaped targets have been proposed which can produce higher ionization fractions. Gopalraja et al. describe in U.S. Pat. No. 6,451,177 a shaped target having an annular vault facing the wafer. A shaped target having a large cylindrical vault is also known. However, shaped targets are significantly more expensive than planar targets.

Copper metallization is generally used in a dual-damascene interconnect structure, such as that illustrated in cross section in FIG. 3. Narrow vias 40 are formed in the lower half of the dielectric layer 14 to form vertical interconnects. The vias 40 connect to a wider trench 42 formed in the upper half and often extending axially over long distances to form horizontal interconnects as well as to provide pads for a further metallization level or for a bonding wire. Typically also, the minimum lateral dimension of the trench 42 is wider than that of the vias 40 in a ratio of at least 1.5 and more typically 2.0 or more to facilitate photomask registry. The conductive features 10 in a multi-level metallization are typically formed by such a trench 42 in the underlying dielectric layer 12. A single metallization process fills both the vias 40 and the trenches 42. Although the geometry is more complex than the simple via illustrated in FIGS. 1 and 2, overhang and filling problems occur also in dual damascene when a metal layer 44, whether of copper or a barrier material, is sputter deposited. Upper overhangs 46 form adjacent the more exposed corners 48 at the top of the trench 42. On the other hand, at the more protected corners 50 between the top of the vias 40 and the bottom of the trench 42, bevels 52 develop in the deposited layer 44 since the trench sidewalls shield the corners 50 from a substantial portion of the isotropic low-energy ions and neutrals, but high-energy ions preferentially sputter etch the exposed corner geometry.

It is known that increasing the wafer bias during sputtering decreases the field coverage, reduces the overhangs, and increases the bottom and sidewall coverage. The overhangs in particular are preferentially sputtered etched during high-bias sputter deposition in other areas. However, this technique has its limitations. Excessive sputter etching of the corner area can form deep facets at the corner and expose the underlying oxide. That is, the barrier may be removed at the corner, whether in barrier or metallization sputter deposition, a very unfavorable result. Furthermore, excessively high biasing also tends to sputter etch rather than sputter deposit at the bottom of the hole, an effect that needs to be carefully considered.

Gopalraja et al. (hereafter Gopalraja) disclose the use of simultaneous oblique ion milling in combination with sputtering in U.S. patent application Ser. No. 10/429,941, filed May 5, 2003, incorporated herein by reference in its entirety and published as U.S. Patent Application Publication US 2004/0222082 A1. In one of Gopalraja's embodiment, an argon ion beam is directed at the wafer at about 15° from the horizontal while the sputtering is proceeding. The ion milling is preferentially directed to the overhangs while the sputtering is heavily ionized and directed toward the bottom of the via. The intent is to prevent the overhangs from ever developing so that the via remains open.

One problem with previous approaches to ion milling has been the poor milling uniformity across the wafer. Gopalraja suggested several approaches to improving uniformity. However, uniform etching of the overhangs requires both uniform ion fluence and similar incidence angles at all vias being etched regardless of their position on the wafer.

Although Gopalraja's process of simultaneous sputter deposition and ion milling shows promise, especially for the very high aspect ratios being contemplated for the 65 nm node and below, further refinements are needed.

### SUMMARY OF THE INVENTION

A sputter reactor including an ion beam especially useful for removing sputter deposited overhangs. The ion beam strikes the wafer at a small incident angle, for example, no more than 35° from the wafer plane and preferably no more than 25°. The sputtering is preferably performed by DC magnetron sputtering with simultaneous angled ion beam etching of the wafer. The beam preferably has a linear shape extending across a wafer diameter in a direction perpendicular to the beam axis and has a width in the perpendicular direction across the narrow dimension of the linear beam that is much less than the wafer diameter, for example, by a factor of at least 5 or 10. The wafer may be rotated about its center so all portions of the wafer are subjected to the ion milling and opposed walls of vias are both exposed to oblique ion milling.

The ion source may be an anode layer source having an inner pole of one magnetic polarity separated by a gap from a surrounding outer pole of the opposed magnetic polarity so that gap forms a closed loop for a plasma loop. Preferably, the gap has two long parallel straight sections joined by two curved ends. An anode underlies the gap and a cathode and aperture therethrough overlies the gap, thereby creating the plasma from an inactive gas such as argon. The ion beam is emitted through the aperture towards the wafer. Conveniently, the cathode forms part of the housing and is grounded while the anode is positively biased.

The width of the aperture may be varied along its length to control the local beam intensity and need not be continuous. For example, the width in the central portion of the straight sections may be decreased over the width at the outer portions to compensate for geometrical effects and thereby make the time-integrated beam intensity more uniform across the rotating wafer.

As the magnetic imbalance is increased, that is, the ratio of the strength of the outer pole to that of the inner pole, the beams may be steered. For example, the two beams emitted from the two straight sections may be made to converge at the lateral wafer diameter. An imbalance ratio of greater than two is preferred.

### BRIEF DESCRIPTION OF THE DRAWINGS

FIGS. 1 and 2 are cross-sectional views of a conventional via coating process in which overhangs develop.

FIG. 3 is a cross-sectional view of a conventional dual-damascene structure including overhangs and bevels which can develop.

FIG. 4 is a schematic cross-sectional view of a sputter reactor incorporating one embodiment of the invention.

FIG. 5 is an orthographic view of an embodiment of a sputter reactor of the invention including an oblique line beam incident on a rotating wafer.

FIG. 6 is a cross-sectional view of one embodiment of an ion source of the invention.

FIG. 7 is a plan view of the magnets and plasma track of the ion source of FIG. 6.

FIG. 8 is a cross-sectional view of the sputter reactor of FIG. 5 and the ion source of FIGS. 6 and 7.

FIG. 9 is a simplified plan view of part of the closed-loop aperture of the ion gun.

FIG. 10 is a graph relating sputter etch rate to magnetic field and anode voltage in the ion gun.

FIG. 11 is a simplified plan view of the plasma loop and closed-path aperture.

FIG. 12 is a schematic graph relating the separation of two linear beams to the imbalance of magnetic fields in the ion gun.

FIG. 13 is a cross-sectional view of a via being simultaneously sputter deposited and ion milled.

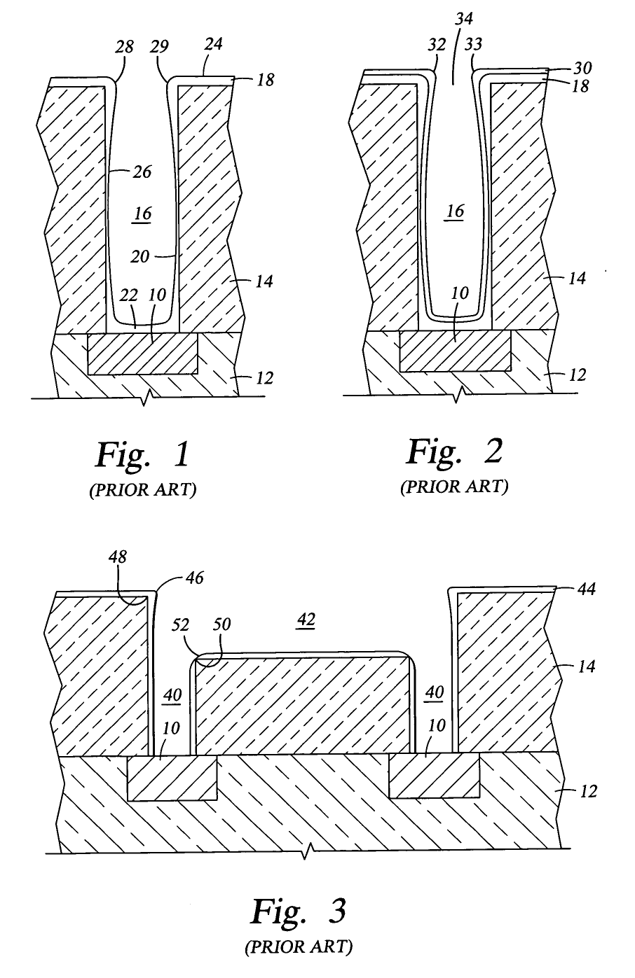

### DETAILED DESCRIPTION OF THE PREFERRED EMBODIMENTS

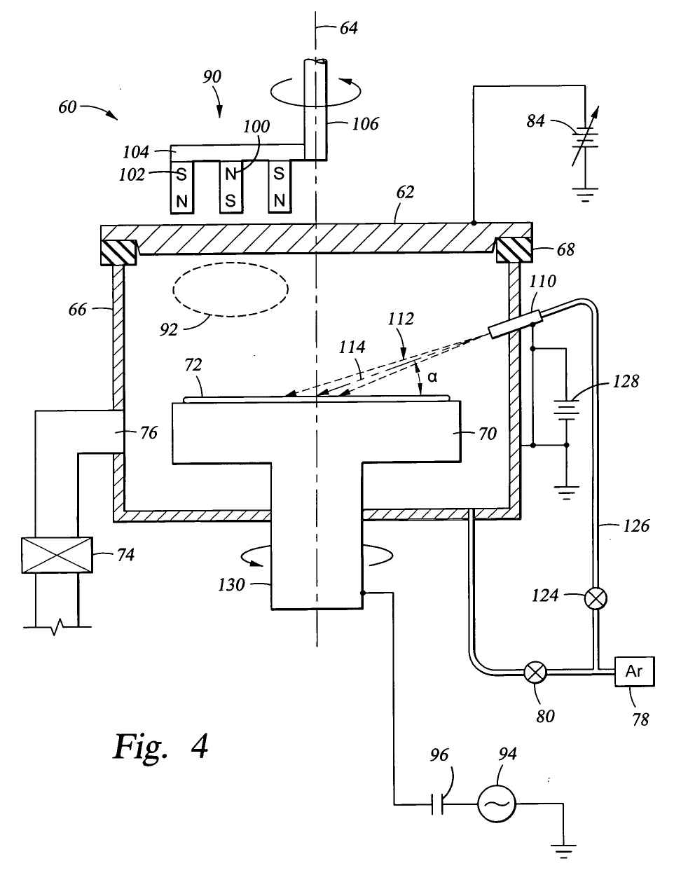

One aspect of the invention improves upon an an embodiment of Gopalraja but uses a single linear ion beam directed at the diameter of a rotating wafer. A sputtering reactor 60 schematically illustrated in FIG. 4 is based upon a self-ionized plasma (SIP) reactor available from Applied Materials and includes many standard components of the commercialized reactor which will be first described. The plasma sputter reactor 60 includes a planar target 62 arranged about a central axis 64 and supported on a grounded chamber body 66 through an annular isolator 68. At least the surface portion of the target 62 is composed of the material to be sputtered, but copper targets are typically fabricated of solid copper. A pedestal electrode 70 supports a wafer 72 to be sputter coated in opposition to the target 62 along the central axis 64 and includes unillustrated chilling fluid lines and thermal transfer gas cavities for controlling the wafer temperature. Unillustrated shields, at least one of which is typically grounded, protect the chamber walls from deposition and also serve as the anode in opposition to the cathode of the negatively biased target 62. A vacuum system 74 pumps the vacuum chamber through a pumping port 76 to a base pressure of less than 10⁻⁶ Torr. However, a sputter working gas, typically argon, is supplied from a gas source 78 through a mass flow controller 80 into the chamber 66. The argon is maintained in the chamber at a few milliTorr for plasma ignition, but for sputtering copper in an SIP reactor the chamber pressure may be reduced to well below 1 milliTorr after ignition.

A controllable DC power supply 84 negatively biases the target 62 to about −400 to −1500VDC, preferably to −800VDC to excite the argon into a plasma and to maintain it in the plasma state. The positively charged argon ions are accelerated towards the negatively biased target 62 and sputter metal atoms from it. Some of the metal atoms strike the wafer 72 and coat it with a metal layer. In reactive sputtering, a reactive gas such as nitrogen, is also admitted into the chamber. The nitrogen reacts with the sputtered metal atoms, for example, tantalum, to form tantalum nitride. Tantalum and tantalum nitride are commonly used as barrier materials between oxide and copper.

A magnetron 90 is positioned in back of the target 62 to produce a magnetic field inside the chamber adjacent the target surface. The magnetic field traps electrons and thus increases the plasma density to form a region 92 of a high-density plasma. The high-density plasma not only increases the sputtering rate but also causes a significant fraction of the sputtered atoms to be ionized. The density of the plasma is increased by a high level of power applied to the target 62 and is further increased by the small magnetron 90 concentrating the sputtering power to a small area of the target 62. Sputtered ions are accelerated to the wafer 72 when an RF power supply 94 coupled to the pedestal electrode 70 through a capacitive coupling circuit 96 induces a negative DC self bias on the pedestal electrode 70 as it interacts with plasma. Even in the absence of RF bias power, a floating electrode will develop a negative bias of about 50 to 60VDC. A high metal ionization fraction also causes some of the metal ions to be attracted back to the target 62 and induce further sputtering, that is, to effect self-ionized sputtering, thereby allowing a plasma to be supported at reduced argon pressure. In the case of copper in a properly designed and operated plasma sputter reactor, the argon supply may be discontinued after the plasma is excited so that the chamber pressure can be reduced to less than 0.2 milliTorr.

In an SIP reactor, the ionization effect is increased by the magnetron 90 being small, nested, and unbalanced. An inner pole 100 of one vertical magnetic polarity is surrounded by an annular outer pole 10 of the opposite magnetic polarity. A magnetic yoke 104 supports and magnetically couples the two poles 100, 102. The total magnetic intensity of the outer pole 102 is substantially larger than that of the inner pole 100 in a ratio of at least 1.5 and preferably 2.0 or more. The unbalanced magnetic field from the outer pole 102 produces a magnetic field component which projects towards the wafer 72, both extending the plasma, supporting a plasma at reduced chamber pressure, and guiding the sputtered metal ions toward the wafer 72. Unillustrated auxiliary magnets on the side of the chamber 66 may be used to further shape the magnetic field. The magnetron 90 has a fairly small size and is, for the most part, disposed away from the central axis 64. To provide more uniform sputtering, the magnetron 90 is supported on and rotated by a rotary drive shaft 106 extending along the central axis 64. No collimator is required since the somewhat axial magnetic field projecting from the unbalanced magnetron 90 somewhat guides and focuses the ionized sputter atoms towards the wafer 72.

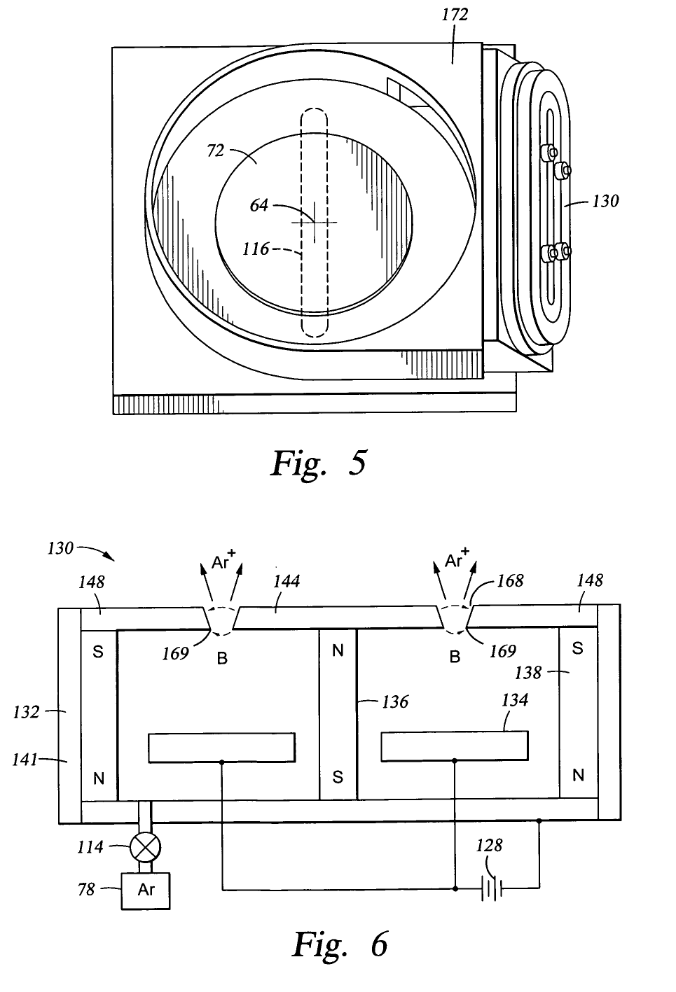

According to one aspect of the invention, an ion gun 110 located above and to the side of the pedestal electrode 70 produces a linear ion beam 112 having a center axis 114 which strikes the wafer 72 near the center 64 of rotation at an angle α of between 10° and 35° with respect to the surface of the wafer 72. The upper limit is more preferably 30° and most preferably 25°. The divergence of the ion beam 112 is relatively narrow so that the beam 112 strikes the wafer with a beam width of a few centimeters, for example, 2.5 cm for a 300 mm wafer measured at some fraction, such as 1/e, of the beam profile. The linear ion beam 112 extends substantially uniformly in the direction perpendicular to the illustration over at least the diameter of the wafer 72 to produce, as illustrated in the orthographic view of FIG. 5, a beam impact area 116 extending uniformly across a diameter of the wafer 72. The beam impact area 116 may have a width of the previously described 2.5 cm and a length of about 50 cm for a 300 mm wafer. The sizes may vary from the stated values. Advantageously, the ratio of the length to the width of the linear beam impact area 116 is greater than 5 and preferably greater than 10. Thereby, the beam extends laterally across the entire wafer but perpendicularly across only a thin portion across a diameter so that geometric effects are reduced.

In particular, the narrow extent of the beam impact area 116 through the center 64 of rotation advantageously produces symmetric milling of the via sidewall since, referring back to FIG. 2, one overhang 32 is milled as a particular via 16 passes through one side of the beam impact area 116 and the opposed overhang 33 is milled as that particular via 16 passes through the other side of the beam impact area 116. Furthermore, the narrow beam divergence means that there is less variation across the wafer radius. In particular, the narrow beam reduces the variations in intensity and inclination angle across the shorter dimension of the beam. The variations across the larger dimension is in large part guaranteed by the linear geometry of the source if end effects are ignored or compensated. As a result, the wafer is ion milled uniformly across its surface. This uniformity is achieved in a relatively small chamber with the ion source positioned close to the edge of the wafer. Nonetheless, the conventional nomenclature of an ion beam will be used to include a beam of neutral atoms.

Returning to the components of the sputter reactor 60 of FIG. 4, the ion gun 110 is supplied with a milling gas, such as argon supplied from the argon source 78 through a mass flow controller 124 and a gas supply line 126 to the ion gun 110. Other milling gases may be used but argon is heavy and thus an effective sputter etching gas, is chemically inactive, is relatively inexpensive, and is already available in the reactor 60. A DC power supply 128 provides a positive voltage relative to the grounded walls of the gun 10 and the main chamber walls 66 to excite the argon into a plasma and then to accelerate and direct the argon ions into an energetic beam producing the ion beam 112. It is noted that the ion gun 110 may rely upon ions to produce and direct the beam 112, it is possible and indeed probable that the ions in the beam 112 are quickly neutralized so that the beam 112 is largely neutral and consists of energetic uncharged argon atoms. A neutral milling beam is advantageous in that it does not interact with sputter ions used to penetrate the deep vias and is undeflected by the extended magnetic fields associated with the SIP magnetron 90 and other magnets which may be used in sputter reactors.

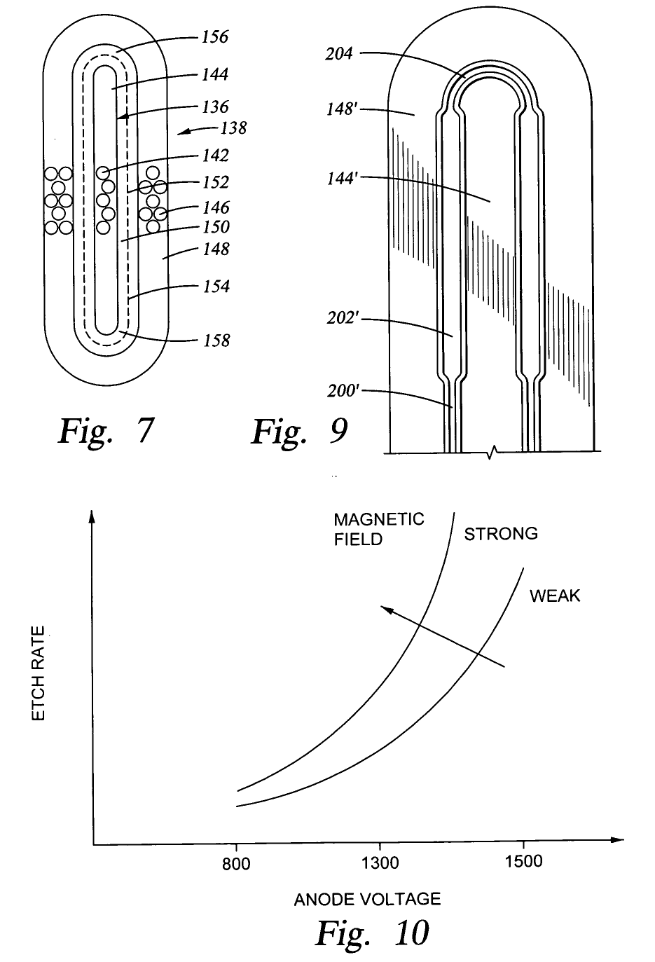

Different types of ion guns are commercially available, for example, from Advanced Energy Industries, Inc. and Veeco, both of Fort Collins, Colo. However, an anode layer source 130, schematically illustrated in the cross-sectional view of FIG. 6, is preferred. It is arranged in a racetrack structure with the view of FIG. 6 showing a cross section of two long parallel sections 154 of the racetrack, which are joined by two semi-circular sections. The argon milling gas is supplied into a grounded case 132 and containing a positively biased racetrack shaped electrode 134. The argon pressure within the case 132 is determined by the amount of argon supplied to it, the size of the apertures to the main chamber, and the pumping speed in the main chamber. Typically, the pressure within the case 132 ranges from above 1 milliTorr to 5 milliTorr while the main chamber pressure for copper sputtering is significantly less than 1 milliTorr. An inner magnet assembly 136 of one magnetic polarity is disposed inside while an outer magnet assembly 138 surrounds the inner magnet assembly 136 with a gap in between. A bottom wall 140 of the case 122 may be formed of magnetic material to acts as a magnetic yoke between the two magnet assemblies 136, 138 while sidewalls 141 are formed of non-magnetic material so as to not short the magnets. The magnet arrangement is better shown in the internal plan view of FIG. 7. The inner magnet assembly 136 includes a plurality of cylindrical permanent magnets 142 (only some of which are shown) of one magnetic polarity having a generally linear staggered arrangement and an inner magnetic pole piece 144 with rounded ends overlying the extent of the distribution of the inner magnets 142. The outer magnet assembly 138 includes a larger plurality of cylindrical permanent magnets 146 (only some of which are shown) of the opposed magnetic polarity and having a generally racetrack arrangement and an outer magnetic pole piece 138 and having the racetrack shape overlying the outer magnets 146. A gap 150 is formed between the two pole pieces 134, 138 having a racetrack shape following a track 152 with two parallel straight sections 154 connected by semi-circular end sections 156, 158. The gap 150 corresponds generally to the interior of the case 132. This magnetic field from the magnet assemblies 132, 136 will support a plasma formed in a closed loop following the track 152. Such a plasma loop is efficient since there is no end loss.

Returning to FIG. 6, the top wall of the case 122 is composed of the pole pieces 144, 148. The two pole pieces 144, 148 act as a cathode electrode grounded to the case 132 and are separated by a racetrack shaped aperture 168 disposed generally in opposition to the positively biased electrode 134. In one embodiment, the width of the aperture 148 is constant along its closed path but is narrower towards the interior of the case 132 to form aperture tips 169. The pole pieces 144, 148 focus a magnetic field B between the magnet assemblies 132, 136 across the aperture 168 and particularly across the opposed aperture tips 169. The DC power supply 128 positively biases the anode electrode 134 with respect to the grounded wall cathodic electrode 144, 148, for example, up to 2000VDC. The biasing excites the argon into a plasma in and around the aperture 168. The high magnetic field B induced in the aperture 168 and between its tips 169 produce a region of high magnetic field, greatly increasing the plasma density near the aperture 168 and the ionization fraction of the argon. The positively charged argon ions are attracted toward the more negative biased wall including the electrodes 144, 148 with increasing energy. Those that strike the two solid portions 144, 148 of the wall cathode are either reflected or absorbed. However, those that travel towards the aperture 168 exit the anode layer source 130 with the energy of the electrical biasing and with a directionality induced by the acceleration generally a direction towards the wall anode electrode 164, 166 producing a high-energy beam with low divergence. However, the strength and numbers of magnets 142, 146 of FIG. 6 can be varied to deflect the ion beam from the normal to the cathodic plate electrode 144, 148.

A more detailed and accurate cross-section view of the mounting of the anode layer source 130 in the cross-sectional view of FIG. 8. The pedestal 70 is mounted on a rotary drive shaft 172, which can also be lowered to present the pedestal 70 to a wafer port 174. An unillustrated robot paddle passes through the wafer port 174 and transfers the wafer 72 to and from the pedestal 70. Three lift pins 176 are attached to a lift arm 178 and can pass through corresponding lift pin holes in the pedestal 70. The rising lift pins 176 lift the wafer 72 from the paddle and then lowers it onto the top surface of the lowered pedestal 70 (the lower position is illustrated by dashed lines), typically partially through the action of raising the pedestal 70. The pedestal 70 is then further raised back to its illustrated operational position.

Different chamber shield configurations may be used, typically two coaxial shields. For simplicity one chamber shield 182 is illustrated which is fixed and grounded to the chamber wall 66 and has a moat-shaped bottom 184 and an aperture 186 for the ion beam 112. An ascending downwardly facing hook section 188 is fixed at the shield bottom 184 to overlap with a corresponding upwardly facing hook section 190 depending from the periphery of the rotating pedestal 70 to shield the bottom of the chamber from sputter coating.

The anode layer source 130, having a generally rectangular shape, is mounted at the inclination angle α on the curved chamber wall 66 through a shaped mount 194.

FIG. 8 illustrates the beam 112 from the upper portion of the gun aperture 168 exiting the gun 130 at approximately normal to its face so that the linear beam extends across the center 64 of the wafer. On the other hand, magnets within the gun are adjusted in strength or number such that the unillustrated beam from the lower portion of the gun aperture 168 exits at a somewhat upward oblique angle so that this resultant linear beam also extends across the center 64 of the wafer.

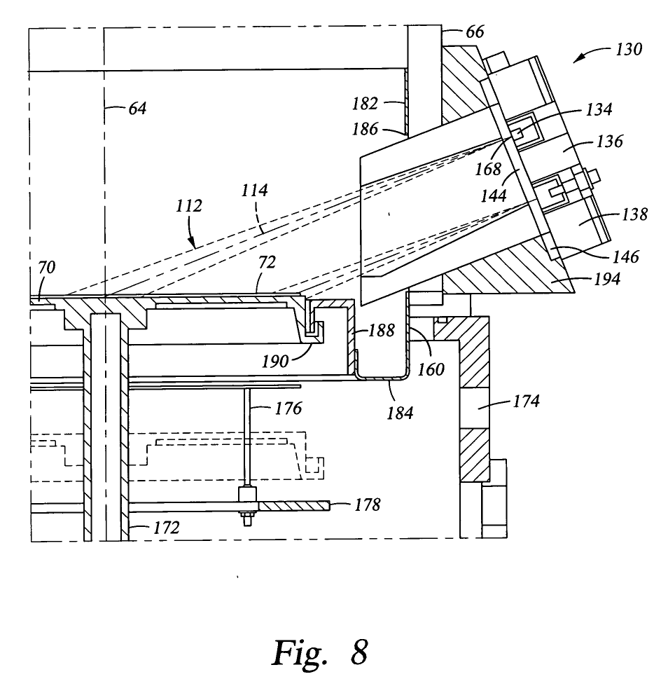

The anode layer source 130 was tested with magnets producing a magnetic field across the gap of between 1340 and 1400 gauss. The electrical plasma characteristics were measured for different values of the anode voltage and the amount of argon supplied into the gun. The discharge current I_{d} at the was measured to be between 0.4 to 4A. The data shown in the graph of FIG. 10 show increase of sputter etch rate with increasing anode voltage and with increasing magnetic field in the anode layer source. Other experiments measured the sputter etch rate produced by the ion beam as a function of the width of the aperture 148 from about 2 mm to 7.5 mm. Over this range, the etch rate varies substantially linearly with the aperture width with some fall off at the smallest aperture.

The ion gun described to this point should produce a substantially constant ion flux across the transverse wafer diameter ignoring the limiting end effects and the effects introduced by the closed plasma loop. However, the wafer is being rotated about its center during sputter etching to improve the sidewall symmetry. Accordingly, uniform sputter etching across the wafer depends upon a uniform ion fluence, that is, flux integrated over time, for the rotating wafer. Generally, the geometry for a beam of constant flux will cause the fluence at any point on the wafer to vary as 1/r, where r is the radius of the point from the wafer's rotation center. That is, the wafer edge is under etched.

In the embodiments described to this point, the width of the aperture 148 has been assumed to be constant. However, the radial asymmetry can in large part be eliminated by varying the width of the aperture around its racetrack path. As illustrated in the plan view of FIG. 9, the shapes of the wall electrodes are modified to produce an outer wall electrode 148′ and a surrounded inner wall electrode 144′ separated by a variable width aperture. In particular, in a central part of the straight sections of the plasma track, a width of an inner aperture 200 is relatively narrow. On the other hand, in an outer part of the straight sections, a width of an outer aperture 202 is considerably increased, for example, by a factor of 2 to 5. Thereby, the beam current exiting the outer aperture 202 is commensurately increased over the beam current exiting the inner aperture 200 to compensate for the opposite geometrical effects on the rotating wafer. In the two semi-circular portions of the plasma track, a width of an end aperture 204 may be chosen to provide better end uniformity. Generally, the end portions of the ion beam do not crucially determine the etching uniformity and the end width is generally chosen to be relatively small. It is not necessary that the aperture overlying the plasma track be continuous so that the end aperture 204 may be bridged over between the two pole pieces 144, 148 or 144′, 148′.

It is of course appreciated that the aperture width in the straight portions may have more than two values and can further be continuously varied over the entire length, typically from a smallest width near the center to two equal and wider widths near the ends.

Typically, the etching rate depends upon the both the acceleration potential of the excitation electrode and the density of the plasma producing the sputter ions. The plasma density depends upon the strength of the magnetic field within the gun. Both effects are illustrated in the graph of the sputter etch rate as a function of anode voltage for a strong and a weak magnetic field.

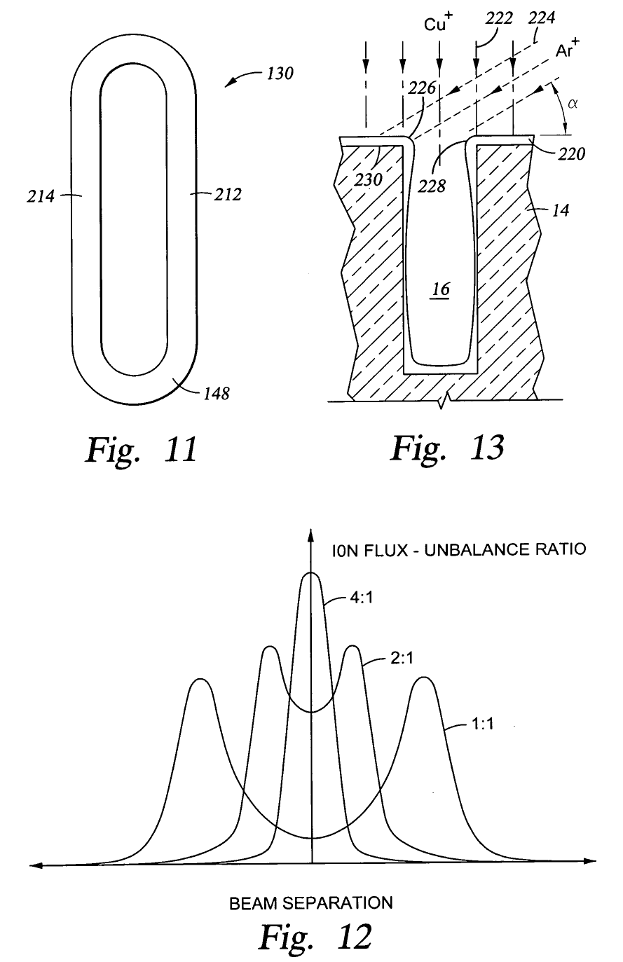

As has been inferred, the direction of the two linear beams exiting the anode layer source 130 can be controlled by the magnetic fields within the source. Generally, it is preferred that the two linear beams exiting the two parallel straight sections 212, 214, illustrated in the plan view of FIG. 11, of the aperture 148 of the anode layer source 130 be controlled in tandem and in complementary fashion. Referring back to the plan view of the magnet arrangement of FIG. 7, the magnetic field distribution and hence the magnet intensity and concentration may be held approximately constant over the straight portions 152, 154 of the plasma track. However, the magnetic intensity of the inner magnet assembly 136 may differ substantially from the magnetic intensity of the outer magnet assembly 138. The ratio of the outer to inner magnetic intensities is referred to as the unbalance ratio. The magnetic intensity is an integral of the magnetic field exiting the respective magnet assembly 136, which in a simple embodiment is the product of the number of magnets and the individual magnet strength. In an even simpler embodiment of magnets 142, 146 having equal size and strength but opposite polarity, the unbalance ratio equals the ratio of the number of magnets in the relevant portions of the inner and outer magnet assemblies 136, 138. The magnets 142, 146 illustrated in FIG. 7 have an unbalance ratio of greater than 2. FIG. 12 schematically illustrates the ion flux across the parallel diameter of the wafer for different values of the unbalance ratio. When the inner and outer magnetic assemblies 136, 138 are balanced, both linear beams exiting the two straight aperture sections 212, 214 are approximately normal to the plane of the source and thus maintain their separation in two distinction peaks and an intermediate deep valley as they strike the wafer. However, as the unbalance ratio is increased to 2:1, the two linear beams are inclined somewhat towards its other and strike the wafer with reduced beam separation and with a shallower body. At about an unbalance ratio of 4:1, the two linear beams are more inclined and strike the wafer at about the point on the parallel diameter, that is, in a single peak with no valley. Accordingly, the anode layer source 130 of FIG. 8 should be designed to produce a single beam at the wafer center 64 and should be aligned with respect to the chamber axis 64 so that both beams obliquely leave the surface of the anode layer source 130.

It is possible to perform separate steps of sputter depositing from the target and ion milling from the ion gun. However, it is preferred to perform both steps simultaneously with sufficient ion milling to prevent the overhangs from developing. As a result, the throat of the via hole always remains clear and allows increased sputter deposition deep into the via hole. In the past, copper seed deposition into high aspect-ratio holes has depended upon a sizable wafer bias to keep the corners from developing overhangs. However, high biases have the disadvantage of etching the exposed planar field area, perhaps removing the barrier layer, and causing complex resputtering within the via and trench. With the simultaneous ion milling of the invention, the wafer bias can be reduced. As illustrated in the cross-sectional view of FIG. 13, a copper layer 220 is deposited with a substantial flux 222 of copper ions, which due to the moderate wafer biasing, are directed towards the bottom of the via hole 16. Simultaneously, an energetic argon flux at an inclination angle α preferentially etches shoulders 226 in the copper layer 220 at the upper corners of the via hole 16. Because of the wafer rotation, an opposed shoulder 288 is similarly milled when the wafer is rotated 180°. The inclined angle α of the ion beam 224 causes the ion milling to be less effective in horizontal field areas 230 on top of the wafer than on the via corners. Also, in most magnetron sputter reactors, the sputtered copper flux contains a substantial neutral component, which deposits the field areas 230 in a more isotropic flux pattern. Because wafer biasing does not need to be raised to high levels to remove the overhangs with energetic copper ions, sputter etching in the field areas 230 may be reduced.

The invention thus allows more uniform sputtering into high-aspect ratio holes under moderate sputtering conditions.

1. A sputter reactor, comprising:
a chamber arranged about and central axis and including a pedestal for supporting a substrate to be processed and to which a sputtering target is affixable in opposition to the pedestal; and
an ion beam source creating a linear particle beam traveling along a central axis towards the pedestal at an inclined angle with respect to a support surface of the pedestal and extending across a lateral diameter of the substrate supported on the pedestal.

2. The reactor of claim 1, wherein the pedestal is rotatable about the central axis.

3. The reactor of claim 1, wherein the inclined angle is no more than 35°.

4. The reactor of claim 3, wherein the inclined angle is no more than 30°.

5. The reactor of claim 4, wherein the inclined angle is no more than 25°.

6. The reactor of claim 1, wherein the ion beam source comprises an anode layer source including:
an inner magnet assembly having a first magnetic polarity;
an outer magnet assembly surrounding the inner magnet assembly, having a second magnetic polarity opposite the first magnetic polarity, and separated from the inner magnet assembly by a closed-loop gap;
a first electrode overlying the gap and including an aperture therethrough overlying at least a linear portion of the gap; and
a second electrode disposed opposite the first electrode in a direction of the inner and outer magnet assemblies.

7. The reactor of claim 6, wherein the aperture forms a closed loop in the first electrode and includes two straight portions connected by two curved portions.

8. The reactor of claim 7, wherein the aperture has a variable width in the straight portions.

9. The reactor of claim 4, wherein an imbalance ratio of a total magnetic intensity of the outer magnet assembly is substantially greater to the total magnetic intensity of the inner magnet assembly is substantially greater than 1.

10. The reactor of claim 9, wherein the imbalance ratio is at least 2.

11. The reactor of claim 9, wherein the aperture includes two parallel straight portions in the first electrode wherein the imbalance ratio is selected to cause two linear beams emitted respectively through the straight portions to strike the pedestal at the central axis.

12. A ion gun, comprising:
a case including a back wall of a magnetic material and a front wall of a magnetic material;
an inner magnet assembly of a first magnetic polarity, having a first total magnetic intensity, disposed between the front and back wall, and having a generally linear arrangement;
an outer magnet assembly of a second magnetic polarity opposite the first magnetic polarity, having a second total magnetic intensity, disposed between the front and back wall, having a generally racetrack arrangement, and surrounding the inner magnet assembly wherein a racetrack-shaped gap is formed between the inner and outer magnet assemblies and wherein parallel apertures are formed in the front wall adjacent straight portions of the race-shaped gap; and
a racetrack-shaped electrode isolated from the front wall and having at least a front surface disposed within the gap;
wherein a ratio of the second total magnetic intensity to the first magnetic intensity is greater than one.

13. The ion gun of claim 12, wherein the ratio is greater than two.

14. The ion gun of claim 12, further comprising a gas port into the interior of the case.

15. The ion gun of claim 12, wherein the front wall is grounded and electrode is positively biased.
